(19) United States
(12) Patent Application Publication
(10) Pub. No.: US 2023/0160981 A1
(43) Pub. Date: May 25, 2023

(54) NON-CONTACT SENSOR ARRANGEMENT FOR FIFTH WHEEL ASSEMBLY

(71) Applicant: SAF-HOLLAND, Inc., Muskegon, MI (US)

(72) Inventor: Randy L. Schutt, Holland, MI (US)

(21) Appl. No.: 18/047,046

(22) Filed: Oct. 17, 2022

Related U.S. Application Data
(60) Provisional application No. 63/264,415, filed on Nov. 22, 2021.

(51) Int. Cl. G01R 33/07; B62D 53/08

(52) U.S. Cl. CPC G01R 33/07; B62D 53/08

(57) ABSTRACT

An electronic system for monitoring a trailer hitch assembly having a hitch plate with a throat for receiving a kingpin of a trailer and a locking mechanism for locking the kingpin in the throat, the electronic system determining whether the trailer hitch assembly is properly coupled to the trailer and including a plurality of magnets each creating a magnetic flux, at least one Hall-effect sensor for sensing the position of a kingpin of a trailer relative to the throat of the hitch plate by measuring the magnetic flux, and a circuit member comprising a magnetically permeable material, wherein the plurality of magnets, the at least one Hall-effect sensor, and the circuit member are each in series with one another.

### CROSS-REFERENCE TO RELATED APPLICATIONS

This application claims the benefit of U.S. Provisional Patent Application No. 63/264,415, filed on Nov. 22, 2021, entitled “NON-CONTACT SENSOR ARRANGEMENT FOR FIFTH WHEEL ASSEMBLY,” the entire disclosure of which is incorporated herein by reference.

### BACKGROUND OF THE INVENTION

The present invention is directed to an electronic system for monitoring the coupling of a trailer to a trailer hitch assembly that is mounted on a truck chassis, and in particular is directed to an electronic system that indicates whether the trailer is properly coupled to the trailer hitch assembly by determining between components of the trailer, components of the hitch assembly and foreign materials.

### BRIEF SUMMARY OF THE INVENTION

One embodiment as disclosed herein may include an electronic system for monitoring a trailer hitch assembly having a hitch plate with a throat for receiving a kingpin of a trailer and a locking mechanism for locking the kingpin in the throat, the electronic system determining whether the trailer hitch assembly is properly coupled to the trailer, where the electronic system includes at least one magnet creating a magnetic flux, the at least one magnet located on a first side of a throat of a hitch plate, a first Hall-effect sensor for sensing the position of a kingpin of a trailer relative to the throat of the hitch plate by measuring the magnetic flux of the at least one magnet, the first Hall-effect sensor located on a second side of the throat substantially opposite the first side, and a second Hall-effect sensor for sensing the position of the kingpin of the trailer relative to the throat of the hitch plate by measuring the magnetic flux of the at least one magnet, where the first Hall-effect sensor located on the second side of the throat substantially opposite the first side, and the second Hall-effect sensor spaced from the first Hall-effect sensor.

Another embodiment as disclosed herein may further or alternatively include an electronic system for monitoring a trailer hitch assembly having a hitch plate with a throat for receiving a kingpin of a trailer and a locking mechanism for locking the kingpin in the throat, the electronic system determining whether the trailer hitch assembly is properly coupled to the trailer, where the electronic system includes a first magnet creating a first magnetic flux, the first magnet located on a first side of a throat of a hitch plate, a first Hall-effect sensor for sensing the position of a kingpin of a trailer relative to the throat of the hitch plate by measuring the first magnetic flux, the first Hall-effect sensor located on a second side of the throat substantially opposite the first side, and a circuit member comprising a magnetically permeable material, wherein the first magnet, the first Hall-effect sensor, and the circuit member are each in series with one another, and wherein the magnetically permeable material of the circuit member has a relative magnetic permeability of within a range of between about 30,000 and about 100,000.

Yet another embodiment as disclosed herein may further or alternatively include an electronic system for monitoring a trailer hitch assembly having a hitch plate with a throat for receiving a kingpin of a trailer and a locking mechanism for locking the kingpin in the throat, the electronic system determining whether the trailer hitch assembly is properly coupled to the trailer, where the electronic system includes a plurality of magnets each creating a magnetic flux, at least one Hall-effect sensor for sensing the position of a kingpin of a trailer relative to the throat of the hitch plate by measuring the magnetic flux, and a circuit member comprising a magnetically permeable material, wherein the plurality of magnets, the at least one Hall-effect sensor, and the circuit member are each in series with one another.

Still yet another embodiment as disclosed herein may further or alternatively include an electronic system for monitoring a trailer hitch assembly having a hitch plate with a throat for receiving a kingpin of a trailer and a locking mechanism for locking the kingpin in the throat, the electronic system determining whether the trailer hitch assembly is properly coupled to the trailer, where the electronic system includes at least one magnet creating a magnetic flux, at least one Hall-effect sensor for sensing the position of a kingpin of a trailer relative to a throat of a hitch plate by measuring the magnetic flux, and a circuit member comprising a magnetically permeable material, wherein the at least one magnet, the at least one Hall-effect sensor, and the circuit member are each in series with one another, and wherein the circuit member is tapered in an area proximate the at least one magnet or Hall-effect sensor.

Another embodiment as disclosed herein may further or alternatively include an electronic system for monitoring a trailer hitch assembly having a hitch plate with a throat for receiving a kingpin of a trailer and a locking mechanism for locking the kingpin in the throat, the electronic system determining whether the trailer hitch assembly is properly coupled to the trailer, where the electronic system includes at least one magnet creating a magnetic flux, at least one Hall-effect sensor for sensing the position of a kingpin of a trailer relative to a throat of a hitch plate by measuring the magnetic flux, a circuit member comprising a magnetically permeable material, and a control arrangement configured to allow a user/microprocessor to adjust the magnetic flux between a first magnitude and a second magnitude that is greater than the first magnitude and/or to adjust the magnetic flux over a range of AC current frequencies.

Yet another embodiment as disclosed herein may further or alternatively include a method for monitoring a trailer hitch assembly having a hitch plate with a throat for receiving a kingpin of a trailer and a locking mechanism for locking the kingpin in the throat and determining whether the trailer hitch assembly is properly coupled to the trailer, where the method includes providing at least one magnet configured to create a magnetic flux at first magnitude and a second magnitude that is greater than the first magnitude, providing at least one Hall-effect sensor for sensing the position of a kingpin of a trailer relative to a throat of a hitch plate by measuring the magnetic flux, providing a circuit member comprising a magnetically permeable material and electrically coupled to the at least one magnet and the at least one Hall-effect sensor, providing a control arrangement configured to allow a user to adjust the magnetic flux between the first magnitude and a second magnitude, adjusting the magnetic flux between the first and second magnitudes, and sensing the magnet flux via the at least one Hall-effect sensor.

These and other features, advantages, and objects of the present invention will be further understood and appreciated by those skilled in the art by reference to the following specification, claims, and appended drawings.

### BRIEF DESCRIPTION OF THE DRAWINGS

FIG. 1 is a schematic view of a truck and trailer arrangement;

FIG. 2 is a bottom plan view of a fifth wheel hitch plate and an electronic sensing system;

FIG. 3 is a side elevation view of the fifth wheel hitch plate and the electronic sensing system;

FIG. 4 is an inverted side elevation view of the fifth wheel hitch plate and the electronic sensing system;

FIG. 5 is a schematic perspective view of an output device;

FIG. 6 is a bottom perspective view of the fifth wheel hitch plate and a first embodiment of the electronic sensing system;

FIG. 7 is a bottom plan view of the fifth wheel hitch plate and the first embodiment of the electronic sensor assembly;

FIG. 8 is an enlarged plan view of the area VIII, FIG. 7;

FIG. 9 is a schematic top plan view of the first embodiment of the electronic sensor assembly, where the electronic sensor assembly is at a zero state;

FIG. 10 is an electronic schematic view of the electronic circuit of the electronic sensor assembly, including a power supply and over current/reverse current protection;

FIG. 11 is a schematic top plan view of the first embodiment of the electronic sensor assembly indicating a location of the kingpin in proper alignment with the hitch plate;

FIG. 12 is a schematic top plan view of the first embodiment of the electronic sensor assembly with a ferromagnetic material positioned within the throat of the hitch plate;

FIG. 13 is a schematic view of a second embodiment of the electronic sensor assembly;

FIG. 14 is a schematic view of a third embodiment of the electronic sensor assembly;

FIG. 15 is a schematic view of a fourth embodiment of the electronic sensor assembly at a zero state;

FIG. 16 is a schematic view of the fourth embodiment of the electronic sensor assembly indicating a location of the kingpin in proper alignment with the hitch plate;

FIG. 17 is a schematic view of the fourth embodiment of the electronic sensor assembly with a ferromagnetic material located within the throat of the hitch plate;

FIG. 18 is an electrical schematic view of the electronic circuit of the fourth embodiment of the electronic sensor assembly; and

FIG. 19 is an electrical schematic view of an alternative embodiment of the electronic circuit of the fourth embodiment of the electronic sensor assembly.

### DETAILED DESCRIPTION OF THE PREFERRED EMBODIMENTS

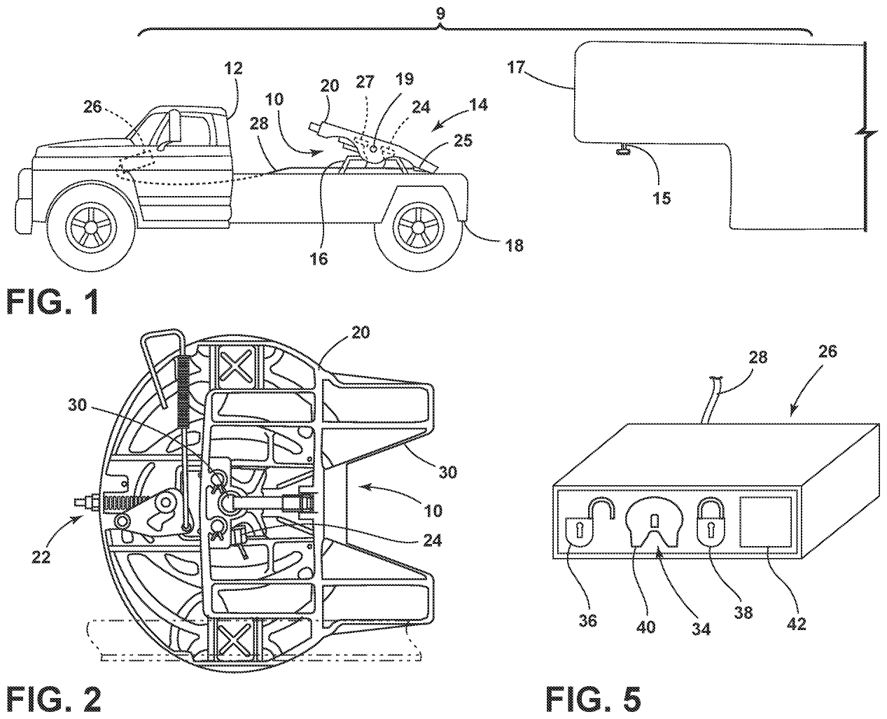

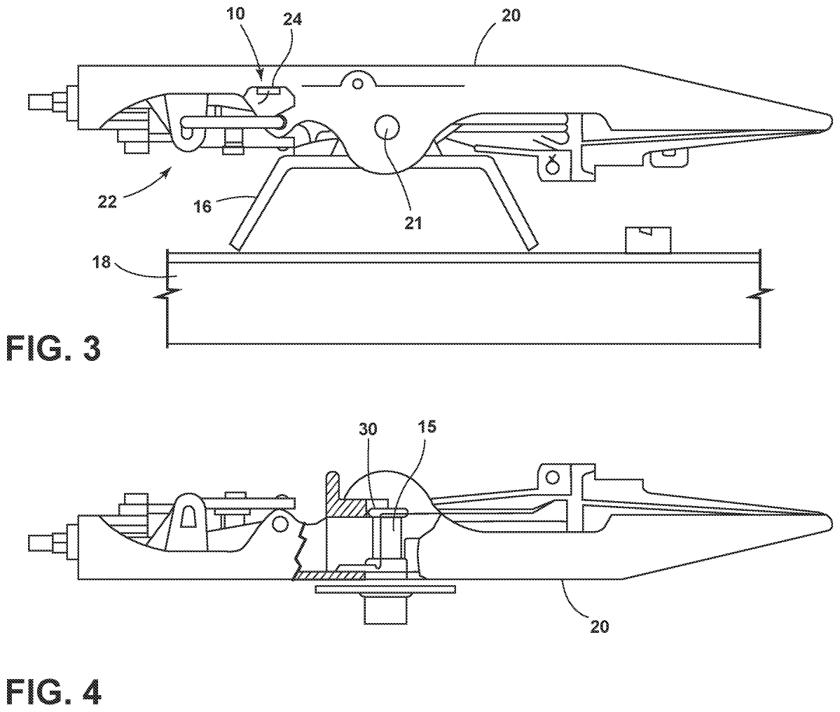

For purposes of description herein, the terms “upper,” “lower,” “right,” “left,” “rear,” “front,” “vertical,” “horizontal,” and derivatives thereof shall relate to the invention as oriented in FIGS. 1-3. However, it is to be understood that the invention may assume various alternative orientations and step sequences, except where expressly specified to the contrary. It is also to be understood that the specific devices and processes illustrated in the attached drawings, and described in the following specification are exemplary embodiments of the inventive concepts defined in the appended claims. Hence, specific dimensions and other physical characteristics relating to the embodiments disclosed herein are not to be considered as limiting, unless the claims expressly state otherwise.

The reference numeral 10 (FIGS. 1-3) generally designates an electronic monitoring and sensing system incorporated within a towing and towed vehicle arrangement 9 that includes a towing truck 10 and a towed trailer 17. A hitch assembly 14 includes a base 16 securely mounted to a chassis 18 of the truck 10, a trailer hitch plate or fifth wheel hitch plate 20 pivotally mounted on the base 16 on a transverse axis 19, and a locking mechanism 22 for locking a conventional trailer kingpin 15 of the trailer 17 in place. The electronic sensing system 10 preferably includes a non-contact kingpin sensor assembly 24 mounted to the hitch assembly 14, a tilt sensor assembly 25, a lock sensor 27, and an output device 26 mounted in the cab of the tractor 12. A contact sensor (not shown) configured to sense contact of the fifth wheel hitch plate 20 with a contact surface on an underside of the towed trailer 17 may be utilized in conjunction with or as an alternative to the sensor assembly 25. The tilt sensor assembly 25 and the lock sensor assembly 27 are described in U.S. Pat. Nos. 5,861,802; 6,285,278; and 6,452,485 which are incorporated herein by reference in their entirety. The sensor assemblies 24, 25, 27 are coupled to the output device 26 by a multi-conductor cable 28. In one embodiment, the non-contact kingpin proximity sensor 24 includes an inductive-type sensor, however, other proximity sensors may be utilized, including Hall-effect type sensors, and the like, as discussed below.

In the illustrated example, the sensor assembly 24 is mounted to the hitch plate 20 near a throat 30 formed in the hitch plate 20, into which a trailer kingpin 15 is positioned and locked. FIG. 4 provides an upside-down or inverted side view in partial cross section illustrating the location of the trailer kingpin 15 when properly disposed within the throat 30 of the hitch plate 20, which includes sensing that the kingpin 15 is fully inserted into the throat of the hitch plate 20 and that the height of the head portion of the kingpin 15 is properly positioned with respect to the relative height location of the hitch plate 20. In the illustrated example, the sensor assembly 24 outputs a detection signal when the kingpin 15 is disposed within the throat 30. The calibration of the sensor assembly 24 prevents it from indicating that the kingpin 15 is present when a misaligned coupling occurs, which prevents the locking mechanism 22 from securing the kingpin 15 to the hitch plate assembly 14 (i.e., the trailer 17 to the truck 12), or further from providing “false-positives” or untrue readings of a proper coupling, as discussed below. The locking mechanism 22 of the hitch plate assembly 14 is biased by a compression spring to automatically lock-in and secure the trailer kingpin 15 as soon as the trailer kingpin 15 enters the hitch throat 30. Those of ordinary skill in the art will appreciate that the present invention may be used in connection with any type of locking mechanism. It should further be noted that the present invention may be applied to tractor hitch assemblies having other constructions and is not limited to particular mounting locations as shown for the embodiments of the sensor assembly 24 described herein.

FIG. 5 illustrates an exemplary output device 26. A multiple conductor cable 28 couples the sensor assembly 24 to the output device 26. The internal components (i.e., the control circuitry) of the output device 26 are further shown and described in U.S. Pat. No. 6,285,278, which is incorporated by reference herein in its entirety. The output device 26 includes a display panel 34 for providing coupling status information to the driver/operator of the tractor or truck 12. It is noted that the output device 26 may also or alternatively include indicator lamps/lights (not shown) mounted on or proximate to the fifth wheel hitch plate 20, and/or may include electronic messaging communicated to a computerized autonomous algorithm by CANbus (Control Area Network) or other electronic communication arrangements. In a preferred embodiment, the display panel 34 includes an “unlocked” icon 36, a “locked” icon 38, a “fifth wheel” icon 40 and seven-segment display 42. In the embodiment, the display 42 provides an error code indicating possible sources of a coupling malfunction, again as further described in U.S. Pat. No. 6,285,278. Preferably, a red light diode (LED) is provided behind the “unlocked” icon 36. Further, a yellow, a red, and green LED are provided behind the “fifth wheel” icon 40 and a green LED is provided behind the “lock” icon 38. One of ordinary skill in the art will appreciate that the individual LEDs could be replaced by an LED array capable of providing multiple colors. While output device 26 as shown only indicates visual indicators, one of ordinary skill in the art will readily appreciate that and audio output may be provided. For example, by adding a speaker and appropriate voice processing circuitry, the output device 26 may provide voice output to instruct a driver as to possible causes of a coupling malfunction. Additionally, a warning buzzer may be activated in addition to, or as an alternative, providing an unlocked icon 36.

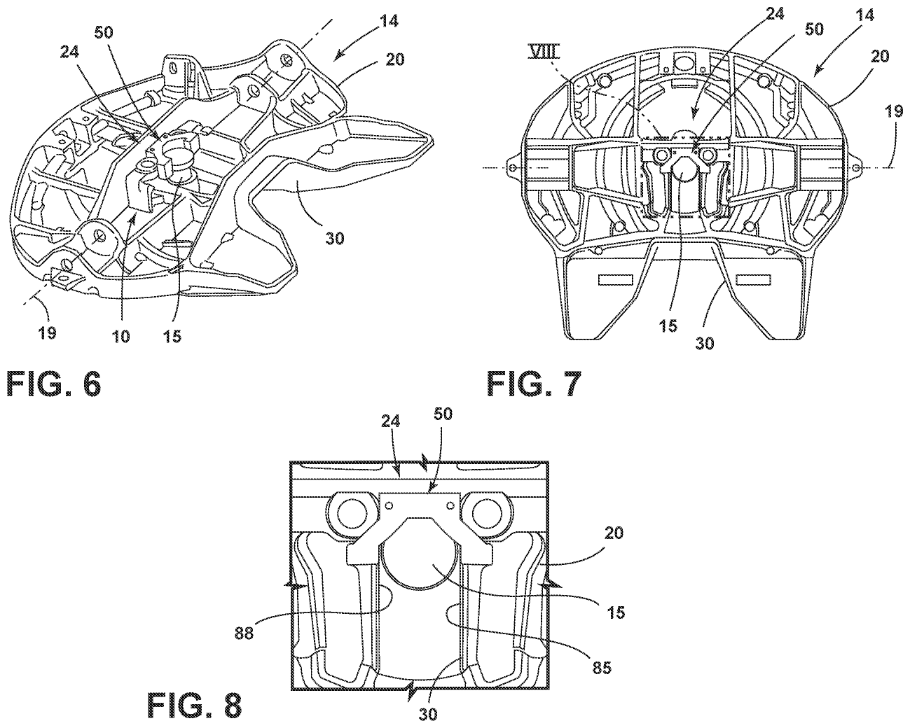

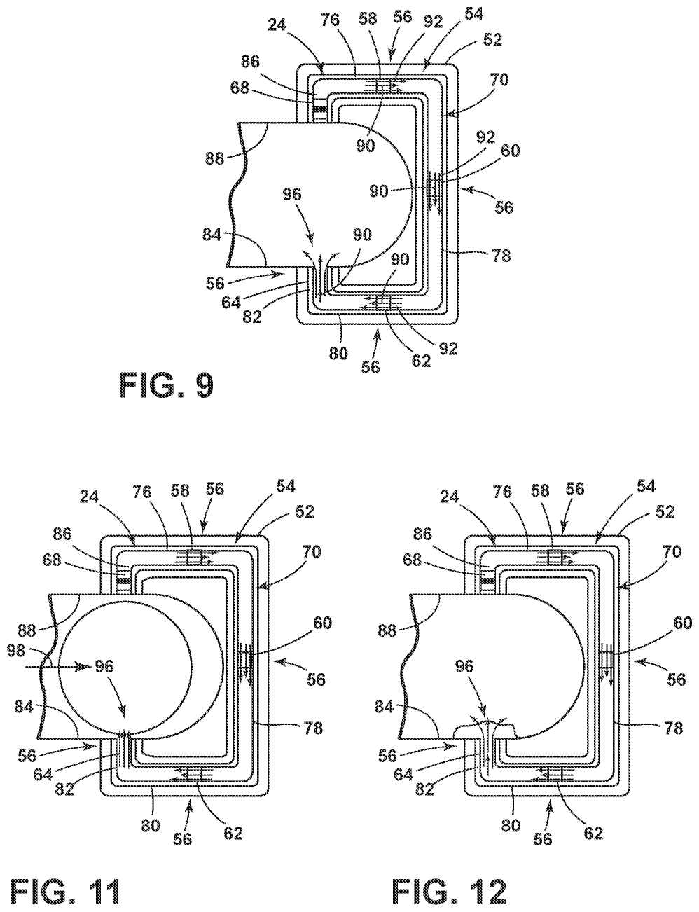

In a first embodiment, the sensor assembly 24 (FIGS. 6-9) includes a bridge circuit arrangement 50 that includes a housing 52 configured to at least partially extend about the kingpin 15 when the kingpin 15 is positioned within the throat 30 of the hitch plate 20. In the illustrated example, the housing 52 (FIG. 9) is further configured to house the sensor assembly 24 that includes a plurality of magnets and a plurality of Hall-effect sensors in series with a circuit member as described below. Specifically, the sensor assembly 24 may include one or more magnets 56 including a first magnet 58, a second magnet 60, a third magnet 62 and a fourth magnet 64, and a sensor such as a Hall-effect sensor 68, each interspaced and sandwiched within a circuit member 70. In the illustrated example, the first magnet 58 is positioned within a first side portion 76 of the circuit member 70, the second magnet 60 is positioned within a forward portion 78 of the circuit member 70, the third magnet 62 is positioned within a second side portion 80 of the circuit member 70, and the fourth magnet 64 is positioned proximate a first end 82 of the circuit member 70 such that the fourth magnet 64 is located proximate a first side 85 of the throat 30 of the hitch plate 20. The magnetic flux created by each of the magnets 56 may be controllable by an operator, as described below.

The Hall-effect sensor 68 is located proximate a second end 86 of the circuit member 70 such that the Hall-effect sensor 68 is located proximate a second side 88 of the throat 30 of the hitch plate 20. It is noted that the magnetic circuit member 70 may be tapered on one or both sides of the magnetic circuit element 70 proximate the Hall-effect sensor(s) 68 to funnel the associated magnetic flux therethrough. While a Hall-effect sensor is shown within the described example, other non-contact sensor arrangements may also be utilized.

The circuit member 70 may comprise a highly magnetically permeable material that has a relative magnetic permeability preferably of within a range of between 30,000 and about 100,000, and more preferably within a range of between 50,000 and 100,000, where the relative magnetic permeability is the ratio of the magnetic permeability of the material relative to the permeability of free space. The circuit member 70 may also comprise about 99.95% pure iron particles. The circuit member 70 may further comprise about 80% Ni and about 20% Fe (a.k.a. permalloy), and/or a packed iron powder of high purity (e.g., 95% or greater).

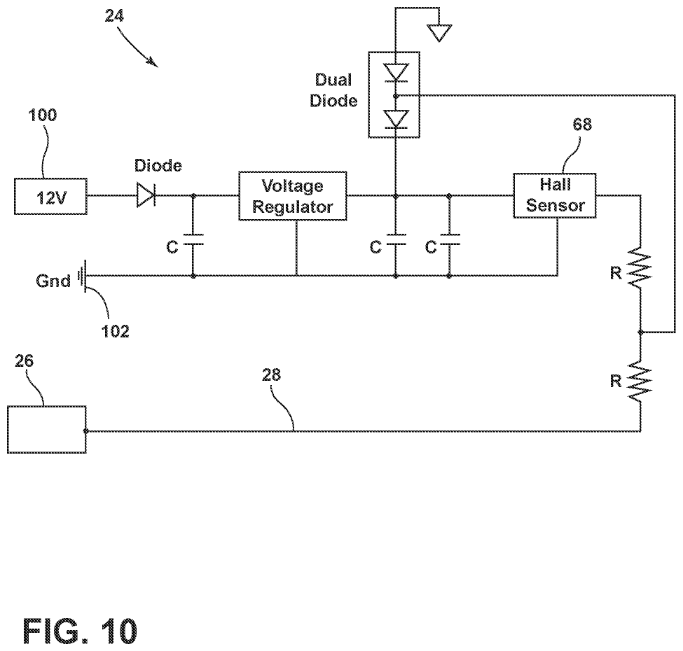

As described above, the sensor assembly 24 may include the analog Hall-effect sensor 68 with an integrated circuit, the biasing magnets 56 each having a magnetic axis 90 and producing a magnetic flux 92, and a threshold adjustment and a switching circuit 94 (FIG. 10). The Hall-effect sensor 68 is sensitive to magnetic flux in a direction perpendicular to the larger dimension thereof. As best illustrated in FIG. 9, the biasing magnets 56 provide a base or zero level flux 96 when the kingpin 15 is not properly located within the throat 30. The strength of the bias magnets 56 and the dynamic range of the Hall-effect device within the sensor 68 determine the effective range of the sensor 68. As illustrated in FIG. 11, with the kingpin 15 moved in a direction as illustrated and represented by directional arrow 98 and positioned proximate the sensor assembly 68, the flux 96 of the magnets 56 as read by the Hall-effect sensor 68 is greater in strength due to the proximity of the ferromagnetic material comprising the kingpin 15. A positive signal is then generated indicating proper location of the kingpin 15 within the throat 30 of the hitch plate 20. As illustrated in FIG. 12, a foreign material, such as grease, water, ice, and the like containing shavings or particles of a ferromagnetic material, commonly referred to as swarf, does not provide an adequate amount of flux 96, per proper calibration of the adjustment and switching circuit 94, in order to indicate a positive and proper location of the kingpin 15 within the throat 30.

The schematic view of the sensor assembly 24 as illustrated in FIG. 10 includes a power supply 100 and a ground 102 each coupled to the Hall effect sensor 68, and the switching circuit 94 configured to supply power to the Hall effect sensor 68. In the illustrated example, the switching circuit 94 includes a voltage regulator 104 configured to supply a constant dc voltage to the Hall effect sensing element, and other components to refine the power produced, or protect the remaining elements of the switching circuit 94. It is noted that most vehicles provide/produce approximately 12 volts as a power input and the switch circuit 94 regulates the power as supplied to the Hall effect sensor to the range of 3.3-5 volts. The illustrated switching circuit 94 is also configured to protect for overvoltage and possible reverse voltage, i.e., improper incoming power connection, although alternatively configured circuits may be utilized.

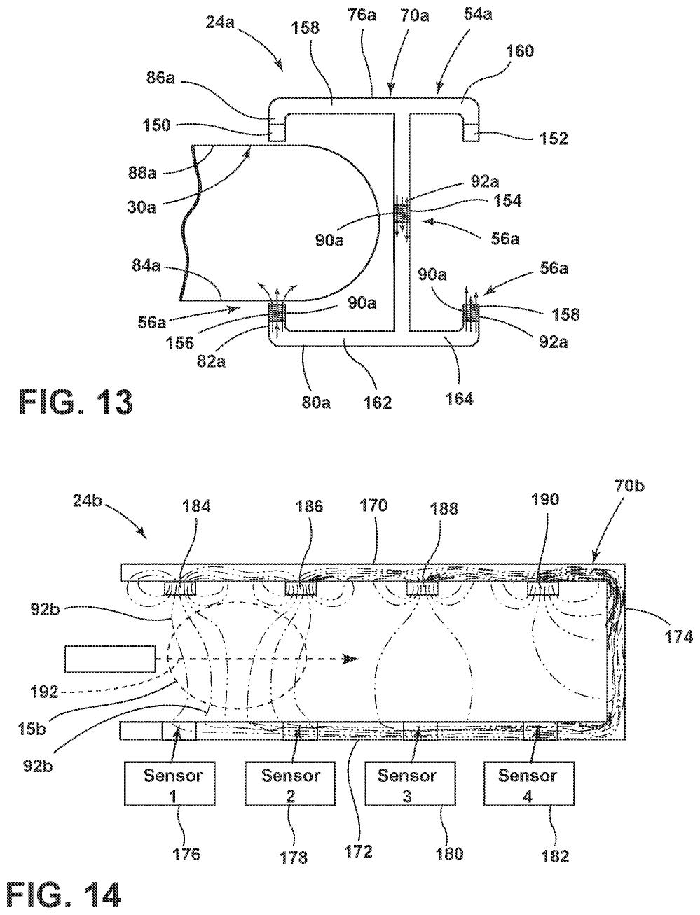

The reference numeral 24a (FIG. 13) generally designates another embodiment of the sensor assembly. Since the sensor assembly 24a is similar to the previously described sensor assembly 24, similar parts appearing in FIGS. 9-12 and FIG. 13 respectively, are represented by the same, corresponding reference numeral, except for the suffix “a” in the numerals of the latter. In the illustrated example, the sensor assembly 24a includes a first Hall-effect sensor 150, a second Hall-effect sensor 152, first, second and third biasing magnets 154, 156, 158 each having a magnetic axes 90a and creating a magnetic flux 92a. In the illustrated example, the first side portion 76a of the circuit member 70a includes a first branch 158 and a second branch 160 while the second side portion 80a of the circuit member 70a includes a first branch 162 and a second branch 164. The circuit member 70a and the overall circuit assembly 54a are configured such that the first Hall-effect sensor 150, the first bias magnet 154, the second bias magnet 156, the first branch 158 of the first side portion 76a of the circuit member 70a and the first branch 162 of the second side portion 80a of the circuit member 70a cooperate to form a first circuit adapted to sense the proper positioning of the kingpin trailer (not shown) within the throat 30a similar to as discussed above with respect to the sensor assembly 24, and where the second Hall-effect sensor 152, the first bias magnet 154, the third bias magnet 158, the second branch 160 of the first side portion 76a of the circuit member 70a and the second branch 164 of the second side portion 80a of the circuit member 70a form a second circuit configured to sense the proper positioning of a second element relative to a given ground, such as the fifth wheel hitch plate or mounting structure thereof. The second circuit arrangement may be configured to sense the proper positioning of elements such as other primary or locking arrangements either associated with the locking of the kingpin within the throat of the fifth wheel, secondary locking arrangements, landing gear, suspension arrangements or components, and the like.

The reference numeral 24b (FIG. 14) generally designates another embodiment of the sensor assembly. Since the sensor assembly 24b is similar to the previously described sensor assembly 24, similar parts appearing in FIGS. 9-12 and FIG. 14, respectively, are represented by the same, corresponding reference numeral, except for the suffix “b” in the numerals of the latter. In the illustrated example, the sensor assembly 24b includes a circuit member 70b having a general U-shaped or bridge configuration, including a first side portion 170, a second side portion 172 and a forward portion 174. In the illustrated example, the sensor assembly 24b includes a plurality of Hall-effect sensors including a first Hall-effect sensor 176, a second Hall-effect sensor 178, a third Hall-effect sensor 180 and a fourth Hall-effect sensor 182 interspaced within the second side portion 172 of the circuit member 70b, and a plurality of bias magnets, including a first bias magnet 184, a second bias magnet 186, a third bias magnet 188 and a fourth bias magnet 190 interspaced within the first side portion 170 of the circuit member 70b, and positioned such that the first, second, third and fourth bias magnets 184, 186, 188, 190 are spaced across from the first, second, third and fourth Hall-effect type sensors 176, 178, 180, 182, respectively. While the illustrated example includes four Hall-effect type sensors 176, 178, 180, 182 and four bias magnets 184, 186, 188, 190, other pluralities of the Hall-effect sensors and/or bias magnets may be utilized, including less than or more than four. Further, although the bias magnets 184, 186, 188, 190 are illustrated as being positioned directly across from corresponding Hall-effect type sensors 176, 178, 180, 182, the bias magnets 184, 186, 188, 190 may be misaligned from the corresponding sensors 176, 178, 180, 182. It is still further noted that the number of magnets 182, 186, 188, 190 do not necessarily need to correspond with the number of sensors 176, 178, 180, 182. In use, the kingpin 15b, or other element may be moved in a direction 192 relative to the sensor assembly 24b, whereby the sensors may be utilized to sense the magnetic flux 92b as it passes through the kingpin 15b while the kingpin 15b is in motion, such that the relative location and motion of the kingpin 15b can be sensed.

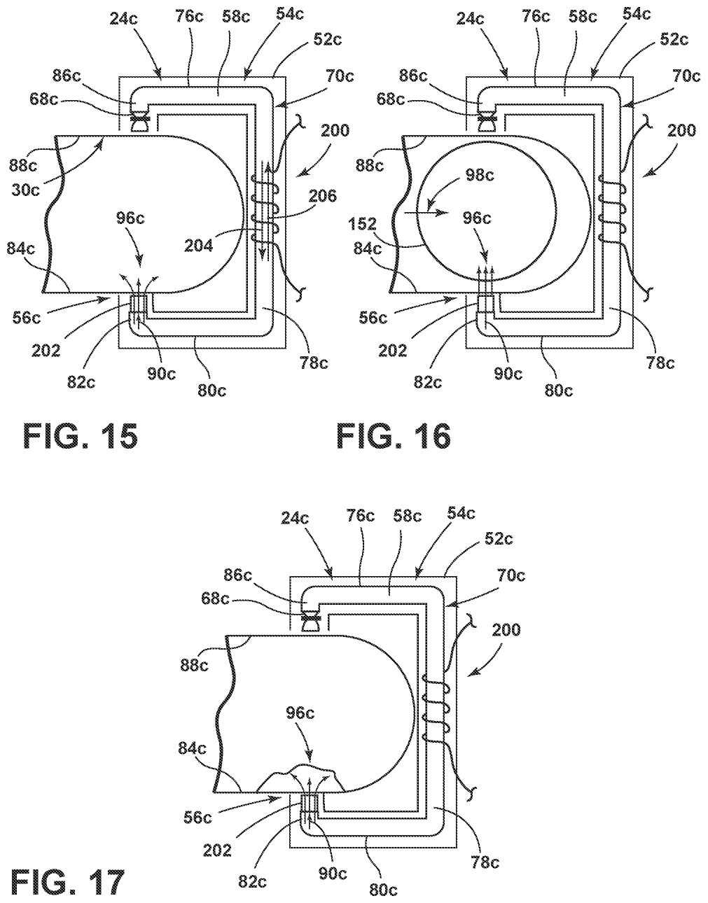

The reference numeral 24c (FIG. 15) generally designates another embodiment of the sensor assembly. Since the sensor assembly 24c is similar to the previously described sensor assembly 24, similar parts appearing in FIGS. 9-12 and FIGS. 15-17, respectively, are represented the same, corresponding reference numeral, except for the suffix “c” in the numerals of the latter. In the illustrated example, the sensor assembly 24c includes a first bias magnet 200, a second bias magnet 202, a Hall-effect type sensor 68c, and a circuit member 70c. As illustrated in FIG. 16, with the kingpin 15c moved in a direction as illustrated in or represented by directional arrow 98c and positioned proximate the sensor assembly 24c, the flux 96 of the magnets 56c and 200 as read by the Hall-effect sensor 68c is greater in strength due to the proximity of the ferromagnetic material comprising the kingpin 15c. A positive signal is then generated indicating proper location of the kingpin 15c within the throat 30c of the hitch plate. As illustrated in FIG. 17, a foreign material, commonly referred to as swarf, does not provide an adequate amount of flux 96c, per proper calibration of the adjustment and switching circuit 94c, in order to indicate a positive and proper location of the kingpin 15c within the throat 30c.

In the illustrated example, the second bias magnet 202 is similar to the previously described bias magnets 58, 60, 64 and is provided proximate to the end 82c of the circuit member 70c, while the Hall-effect sensor 68c is provided proximate to the end 86c of the circuit member 70c. The first bias magnet 200 may include a magnet arrangement providing a magnetic flux that is controllable by an operator or controller. In the illustrated example, the first bias magnet 200 comprises a coil or solenoid-type magnet that extends about the forward portion 78c of the circuit member 70c. The coil-type magnet 200 allows a user or controller, such as a controller associate with an autonomous vehicle control arrangement, to control the amount and/or frequency of current, particularly an AC current, and change the strength of the magnetic field as provided thereby, thereby allowing fine tuning of the overall magnetic frequency to avoid false positives caused by swarf located within the throat 30c and the air gap of the electronic sensor system 10. It is noted that the relative permeability of the various elements within the system, such as the kingpin 15c and any potential contaminating swarf material is frequency dependent, such that controlling the frequency of the coil magnet 200 may allow the user to tune the sensor assembly 24c to sense only the permalloy material of the circuit member 70a and the material of the kingpin 15c, thereby reducing the likelihood of false-positives. Still further, the coil magnet 200 may be configured such that an operator or controller may pass a relatively large current in alternating directions, such as the normal operating forward direction 204 and a reversed direction 206, thereby minimizing the effect of the swarf on the overall sensor reading from the Hall-effect type sensor 68c. Currents generated by the coil magnet 200 may also be utilized to force contaminants, such as metal debris, from within the overall swarf material or force the swarf material from either within or to a different position within the throat 30c, thereby minimizing the effects of the swarf on the sensor 68c. Still further, the controllability of the coil magnet 200 would allow a controller or user to activate the coil magnet 200 only during coupling and/or uncoupling of the kingpin with the associated fifth wheel hitch plate, thereby reducing or eliminating the magnetic flux and attraction force as associated therewith generated by the coil magnet 200, and as a result reducing the effects of contamination and swarf buildup caused by the magnetic flux during general vehicle operations.

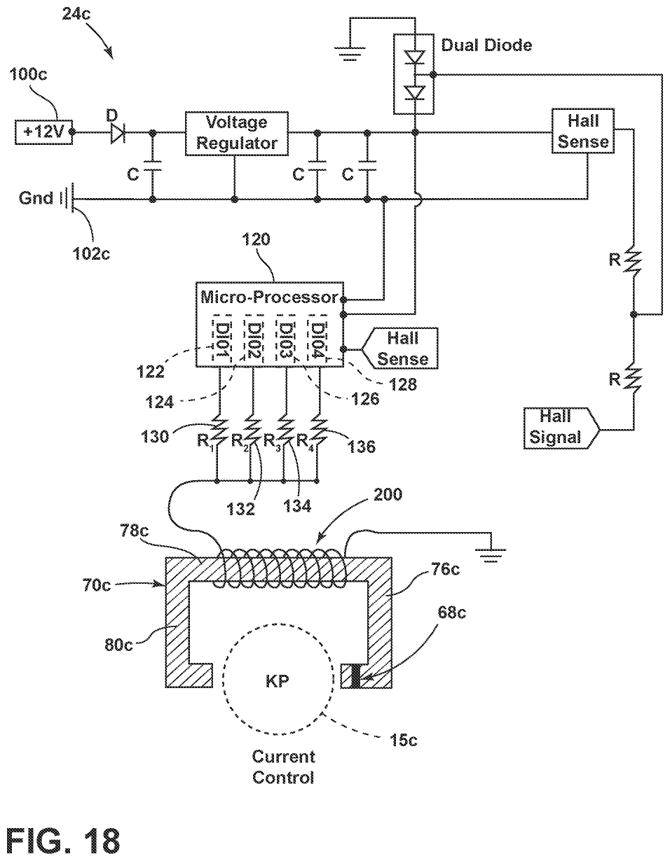

The schematic view of an embodiment of an electronic circuit of the sensor assembly 24c is illustrated in FIG. 18, where the circuit 24c is configured to control varying levels of electrical current as an input into the first bias magnet 200 which may include a coil configured to induce a magnetic flux into the circuit member 70c. The power supply circuit as previously described supports the operation of the Hall effect sensor 68c. An output signal from the Hall effector sensor 68c may be utilized as input to a microprocessor 120 and logically used for determining the presence of the kingpin 15c. The microprocessor 120 is algorithmically configured to drive several outputs, including DIO1-D1O4 122, 124, 126, 128, respectively. While four outputs 122, 124, 126, 128 are included in the illustrated example, it is noted that more or fewer outputs may be provided, as determined by the desired flux levels. In operation, powering an output 122-128 drives a current which is determined by the magnitude of resistance R1 through R4130, 132, 134, 136 in each output circuit, respectively. The differing levels of current produces the desired levels of magnetic flux in the magnetic circuit. Sampling over different fluxes may be utilized to significantly improve the detection of the kingpin, or assist in discriminating between kingpin and contaminant swarf material.

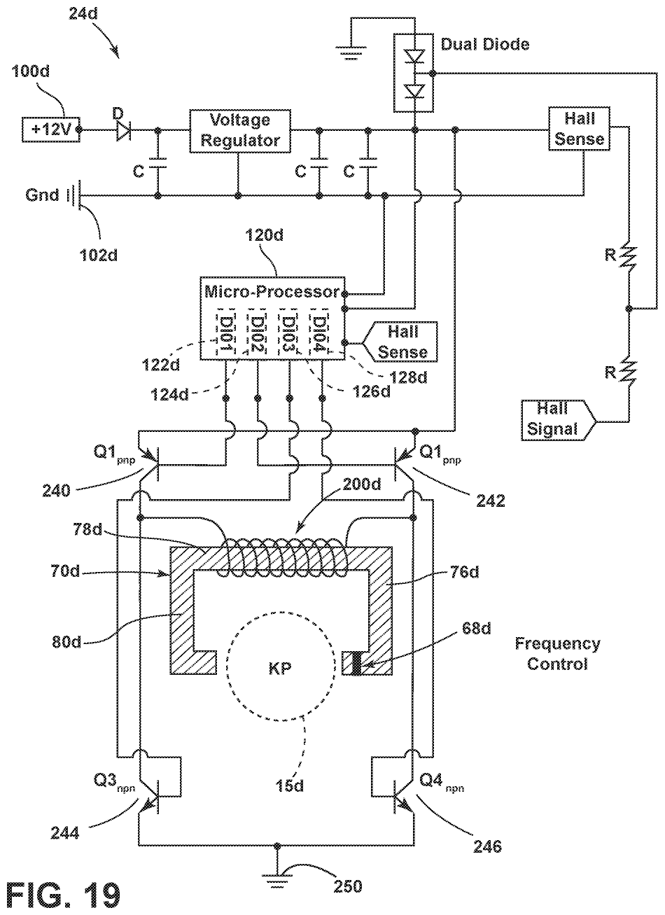

FIG. 19 illustrates an alternative embodiment of an electronic circuit of the sensor assembly 24d where circuit 24d is configured to provide different frequencies of electric current to the first bias magnet or coil 200d that is used to induce magnetic flux into the circuit member 70d. In the illustrated example, changing the frequency of the electric current also changes the flux in the circuit member 70d in a similar manner. The circuit member 70d uses the same power supply circuit previously described for powering the Hall effect sensor 68d. A sensor output signal is supplied as an input to the control logic in the microprocessor 120d which is configured to use the sensor output signal as needed to detect the presence of the kingpin 15d. The microprocessor 120d also controls the direction of electric current by controlling a plurality of transistor switches Q1-Q4 240, 242, 244, 246, respectively, that channel electric current into, and out of the coil 200d which induces flux into the circuit member 70d. To produce current in one direction and therefore magnetic flux in one direction in the circuit member 70d the microprocessor 120d controls the digital outputs D1O1-D1O4 122d, 124d, 126d, 128d, respectively. In operation, when the microprocessor 120d activates DIO1 122d and DIO4 128d and does not activate D1O2 124d and D1O3 126d electric current flows into the coil 200d, through Q1 240 as controlled by DIO1 122d, from the upper left in the schematic diagram of FIG. 19 and out of the coil 200d to ground 250, through Q4 246 as controlled by DIO4 128d. This direction of current flow produces a flux in the circuit member 70d in one direction. To activate current flow in the opposite direction and produce magnetic flux in the circuit member 70d which is opposite to the first direction as described above, the microprocessor 120d deactivates DIO1 122d and DIO4 128d and activates DIO2 124d thereby allowing current to flow through Q2 242 into the coil 200d in an opposite direction and DIO3 126d thereby allowing current to flow out of coil 200 and to ground 250 through Q3 244. By controlling the rate of the switching between these two states the frequency of the current, and the induced magnetic flux in the circuit member 70d may be controlled. This switching control can be done at several different frequencies thereby allowing the Hall effect sensor 68d to measure the output at the same time. It is noted that the different materials, namely the kingpin 15d and the contaminant swarf material have frequency dependent permeabilities, such that the desired switch control provides an improved ability to distinguish between the kingpin 15d and any confusing or unwanted output signals due to the contaminant swarf material.

In the foregoing description, it will be readily appreciated by those skilled in the art that modifications may be made to the invention without departing from the concepts disclosed herein. Such modifications are to be considered as included in the following claims, unless these claims by their language expressly state otherwise.

The invention claimed is:

1. An electronic system for monitoring a trailer hitch assembly having a hitch plate with a throat for receiving a kingpin of a trailer and a locking mechanism for locking the kingpin in the throat, the electronic system determining whether the trailer hitch assembly is properly coupled to the trailer and comprising:
a first magnet creating a first magnetic flux, the first magnet located on a first side of a throat of a hitch plate;
a first Hall-effect sensor for sensing the position of a kingpin of a trailer relative to the throat of the hitch plate by measuring the first magnetic flux, the first Hall-effect sensor located on a second side of the throat substantially opposite the first side; and
a circuit member comprising a magnetically permeable material, wherein the first magnet, the first Hall-effect sensor, and the circuit member are each in series with one another, and wherein the magnetically permeable material of the circuit member has a magnetic permeability of within a range of between about 30,000 and about 100,000.

2. The electronic system of claim 1, wherein the magnetically permeable material of the circuit member comprises about 99.95% pure iron particles.

3. The electronic system of claim 1, wherein the circuit member comprises about 80% Ni and about 20% Fe.

4. The electronic system of claim 1, wherein the circuit member comprises a packed iron powder.

5. The electronic system of claim 1, further comprising:
a second magnet creating a second magnetic flux, the second magnet located on the first side of a throat of the hitch plate; and
a second Hall-effect sensor for sensing the position of the kingpin of the trailer relative to the throat of the hitch plate by measuring the second magnetic flux.

6. The electronic system of claim 5, where the second magnet and the second Hall-effect sensor are in series with the first magnet, the first Hall-effect sensor and the circuit member.

7. The electronic system of claim 1, wherein the first magnetic flux is variable and controllable by an operator and/or an autonomous vehicle control arrangement.

8. The electronic system of claim 1, wherein the first magnet comprises an electromagnet.

9. An electronic system for monitoring a trailer hitch assembly having a hitch plate with a throat for receiving a kingpin of a trailer and a locking mechanism for locking the kingpin in the throat, the electronic system determining whether the trailer hitch assembly is properly coupled to the trailer and comprising:
at least one magnet creating a magnetic flux;
at least one Hall-effect sensor for sensing the position of a kingpin of a trailer relative to a throat of a hitch plate by measuring the magnetic flux;
a circuit member comprising a magnetically permeable material; and
a control arrangement configured to allow a user to adjust the magnetic flux between a first magnitude and a second magnitude that is greater than the first magnitude.

10. The electronic system of claim 9, wherein the at least one magnet comprises an electromagnet.

11. The electronic system of claim 10, wherein the electromagnet includes an excitation coil.

12. The electronic system of claim 9, wherein the first magnitude is zero.

13. The electronic system of claim 9, wherein the at least one magnet includes a plurality of magnets.

14. The electronic system of claim 13, wherein the control arrangement is configured to allow the user to adjust the magnetic flux from each of the magnets of the plurality of magnets separate from one another.

15. The electronic system of claim 9, wherein the at least one magnet, the at least one Hall-effect sensor, and the circuit member are each in series with one another.

16. The electronic system of claim 9, wherein the at least one magnet is located on a first side of the throat of a hitch plate, and wherein the at least one Hall-effect sensor is located on a second side of the throat of the hitch plate substantially opposite the first side.

17. A method for monitoring a trailer hitch assembly having a hitch plate with a throat for receiving a kingpin of a trailer and a locking mechanism for locking the kingpin in the throat and determining whether the trailer hitch assembly is properly coupled to the trailer, the method comprising:
providing at least one magnet configured to create a magnetic flux at a first magnitude and a second magnitude that is greater than the first magnitude;
providing at least one Hall-effect sensor for sensing the position of a kingpin of a trailer relative to a throat of a hitch plate by measuring the magnetic flux;
providing a circuit member comprising a magnetically permeable material and electrically coupled to the at least one magnet and the at least one Hall-effect sensor;
providing a control arrangement configured to allow a user to adjust the magnetic flux between the first magnitude and a second magnitude;
adjusting the magnetic flux between the first and second magnitudes; and
sensing the magnet flux via the at least one Hall-effect sensor.

18. The method of claim 17, wherein the at least one magnet comprises an electromagnet.

19. The method of claim 18, wherein the electromagnet includes an excitation coil.

20. The method of claim 17, wherein the first magnitude is zero.

21. The method of claim 17, wherein the at least one magnet includes a plurality of magnets.

22. The method of claim 21, further comprising:
adjusting the magnetic flux of each of the magnets of the plurality of magnets separate from one another.

23. The method of claim 17, wherein the at least one magnet, the at least one Hall-effect sensor, and the circuit member are each in series with one another.

24. The method of claim 17, wherein the at least one magnet is located on a first side of the throat of a hitch plate, and wherein the at least one Hall-effect sensor is located on a second side of the throat of the hitch plate substantially opposite the first side.
